(19) United States
(12) Patent Application Publication
(10) Pub. No.: US 2020/0219743 A1
(43) Pub. Date: Jul. 9, 2020

(54) WAFER TRANSFER BOX AND WAFER AUTOMATIC TRANSFER SYSTEM

(71) Applicant: SHANGHAI MICRO ELECTRONIC EQUIPMENT (GROUP) CO., LTD., Shanghai (CN)

(72) Inventors: Jing ZHEN, Shanghai (CN); Qixin XU, Shanghai (CN); Gang WANG, Shanghai (CN); Li ZHANG, Shanghai (CN); Xinjiang LONG, Shanghai (CN); Xiping CHEN, Shanghai (CN)

(21) Appl. No.: 16/626,171

(22) PCT Filed: Jun. 19, 2018
(86) PCT No.: PCT/CN2018/091876

§ 371 Date: Dec. 23, 2019

(30) Foreign Application Priority Data
Jun. 23, 2017 (CN) 201710488240.4

(51) Int. Cl. H01L 21/673; H01L 21/677

(52) U.S. Cl. CPC H01L 21/67386; H01L 21/67379; H01L 21/67772

(57) ABSTRACT

A wafer transfer cassette and an automated wafer transfer system. The wafer transfer cassette includes a wafer storage frame configured to accommodate wafers, a base, a casing, a cover and a rotary coupling mechanism. The base and the casing are fixedly connected to each other and together define a cavity in which the wafer storage frame is accommodated. The casing defines an opening through which a wafer can be placed in or taken out. The cover is pivotally coupled to the casing by means of the rotary coupling mechanism so that when the rotary coupling mechanism is rotated, the cover slides on the base and thus opens or closes the opening.

### TECHNICAL FIELD

The present invention relates to the technical field of microelectronic processing and, more specifically, to a wafer transfer cassette and an automated wafer transfer system.

### BACKGROUND

Integrated circuits (ICs) have been widely used in electronic products, such as computers, industrial control equipment and consumer electronics, and IC design, manufacturing and other related technologies are rapidly developing with the fast advancement of electronic products. Most of IC components are fabricated on wafers.

Wafers used in the manufacture of ICs are liable to be contaminated by any kind of particles such as fine particulates, dust, organic matters and so on, which may give rise to defects and lower the quality of ICs being fabricated. For this reason, it is necessary for ICs to be fabricated in a clean environment. Wafers stored on selves in rooms are usually directly exposed to the ambient air. If the rooms' cleanness is not high enough, wafers will suffer from easy contamination during transportation. However, it is not easy to control the cleanness of the rooms. Moreover, a higher requirement on the cleanness of the rooms is desired in view of the higher requirement on quality of ICs, which leads to a significant increase in manufacturing cost. Therefore, it is desired to provide a wafer transfer cassette that can protect wafers from direct exposure to the ambient air, thus reducing the requirements on cleanness of such rooms. Further, since most IC production lines are automated, it is also desired that such a wafer transfer cassette is able to be opened and closed automatically in order to ensure a high IC production throughput.

### SUMMARY OF THE INVENTION

An objective of the present invention is to provide a wafer transfer cassette and automated wafer transfer system, to solve the problem that the wafer is contaminated and the wafer transfer cassette is not able to be opened or closed automatically during transportation.

To this end, the present invention provides a wafer transfer cassette, configured to accommodate a wafer storage frame, wherein the wafer transfer cassette comprises a base, a casing, a cover and a rotary coupling mechanism, the base and the casing being fixedly connected to each other and together define a cavity for accommodating the wafer storage frame, the casing defining an opening through which a wafer can be placed in or taken out, the cover pivotably coupled to the casing by means of the rotary coupling mechanism so that when the rotary coupling mechanism rotates, the cover slides on the base and thus opens or closes the opening.

Optionally, the wafer transfer cassette further comprises a pressing mechanism, which is disposed on a surface of the cover that faces toward the wafer storage frame and is elastically scalable with respect to the cover, wherein during movement of the cover, the pressing mechanism is able to apply a force to a wafer in the wafer storage frame in a plane of the wafer so as to adjust the position of the wafer.

Optionally, the pressing mechanism comprises a push bar, a scalable link and a spring, the scalable link having two ends respectively connected to the cover and the push bar, the spring sleeving over the scalable link, the spring configured to provide the push bar with an axial preload during movement of the push bar in an axial direction of the scalable link.

Optionally, a lengthwise direction of the push bar is parallel to an axis of the wafer storage frame, and wherein a length of the push bar is not less than a total height of wafers able to be stored in the wafer storage frame.

Optionally, the base is provided thereon with a guide member configured to guide the cover to slide.

Optionally, the guide member is a groove formed in the base, and the cover is able to slide along the groove.

Optionally, the wafer transfer cassette further comprises at least one rolling bearing fixed to an inner side of the cover and brought into rollable contact with the base.

Optionally, the rolling bearing is a resin bearing.

Optionally, the rotary coupling mechanism comprises a rotating shaft, a rotating bearing and a connecting member, the rotating bearing being fixed to the casing, one end of the rotating shaft going through the rotating bearing and coupled to one end of the connecting member, a further end of the rotating shaft protruding out of the casing and serving as a driving end, a further end of the connecting member fixedly connected to the cover.

Optionally, the casing comprises a top opposite the base, the rotating shaft protruding out of, and rotatably coupled to, the top of the casing, and wherein the rotating shaft is disposed at a center of the top of the casing.

Optionally, the connecting member is implemented as a link bar, wherein at least two link bars are disposed between the cover and the rotating shaft and arranged at an angle with respect to each other.

Optionally, the base is provided thereon with a frame locating mechanism configured to match and connect with a bottom of the wafer storage frame.

Optionally, the frame locating mechanism is a frame locating groove or a frame locating protrusion.

Optionally, attractive fastener assemblies are respectively provided on two sides of the cover along a slide direction of the cover and at corresponding locations of the casing, in order to attach the cover to the casing by attraction when the opening is fully closed or fully opened.

Optionally, the cover is arched and configured to slide along an arched path on the base in order to open or close the opening.

The present invention also provides an automated wafer transfer system, configured to transfer wafers between a plurality of wafer processing stations, between the plurality of wafer processing stations and a plurality of wafer storage areas, and/or between the plurality of wafer storage areas, wherein the automated wafer transfer system comprises a wafer transfer cassette as claimed in any one of claims 1 to 15, a flange being arranged on the casing of the wafer transfer cassette; a rotary driving mechanism configured to cause a rotation of the rotary coupling mechanism; and an automated transfer apparatus configured to transport the wafer transfer cassette by grasping the flange.

Optionally, each of the wafer processing stations and/or wafer storage areas is provided with a wafer cassette stage having a bearing surface configured to match and connect with the wafer transfer cassette.

In the wafer transfer cassette and automated wafer transfer system provided in the present invention, since the wafer storage frame configured to store wafers is accommodated in the cavity defined by the base and casing, wafer contamination during transportation can be prevented. Additionally, the cover of the cassette is driven to move along an arched path by the rotary coupling mechanism, which cause the cover to open or close the opening which is defined in the casing and configured to allow wafers to be placed in or taken out, and thus automatic opening and closing of the wafer transfer cassette can be achieved.

### BRIEF DESCRIPTION OF THE DRAWINGS

FIG. 1 is a schematic structural diagram of a wafer transfer cassette according to an embodiment of the present invention, with its cover in a closed state.

FIG. 2 is a schematic structural diagram of a wafer transfer cassette according to an embodiment of the present invention, with its cover in an open state.

FIG. 3 is a schematic structural diagram of a part of the wafer transfer cassette according to an embodiment of the present invention.

FIG. 4 is a simplified schematic cross-sectional view of the wafer transfer cassette according to an embodiment of the present invention.

FIG. 5 is a top view of a base according to a first embodiment of the present invention.

FIG. 6 is a top view of a base according to a second embodiment of the present invention.

FIG. 7 is a bottom view of a wafer transfer cassette according to the second embodiment of the present invention.

### LIST OF REFERENCE NUMERALS IN THE DRAWINGS

10 Wafer Storage Frame
20 Base
30 Casing
31 Top
32 First Connecting Portion
331 Frame Locating Groove
332 Frame Locating Protrusion
34 Locating Leg
40 Cover
50 Pressing Mechanism
51 Push Bar
52 Scalable Link
60 Rotary Coupling Mechanism
61 Rotating Shaft
62 Connecting Member
63 Bearing Seat
W Wafer
71 Cavity
72 Opening
81 Guide Member
82 Rolling Bearing
83 Attractive Fastener Assembly

### DETAILED DESCRIPTION

Specific embodiments of the wafer transfer cassette and automated wafer transfer system proposed in the present invention will be described below with reference to the accompanying drawings. Features and advantages of the invention will be more apparent from the following detailed description, and from the appended claims. Note that the accompanying drawings are provided in a very simplified form not necessarily presented to scale, and only intend to facilitate convenience and clarity in explaining the embodiments.

### Embodiment 1

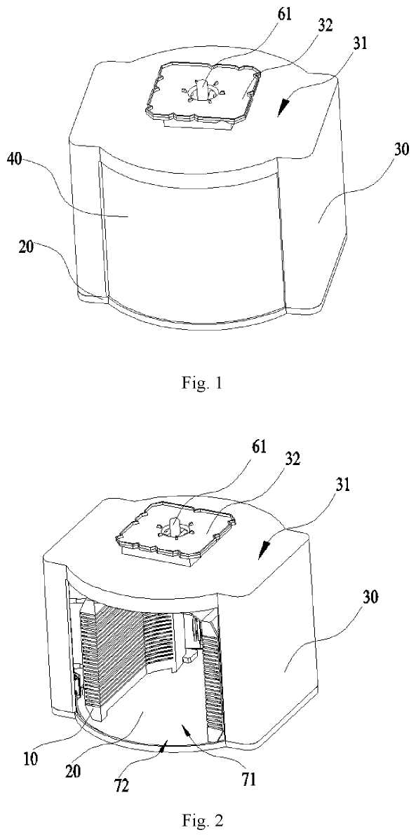

FIG. 1 is a schematic structural diagram of a wafer transfer cassette according to an embodiment of the present invention, with its cover in a closed state, while FIG. 2 is a schematic structural diagram of the wafer transfer cassette according to an embodiment of the present invention, with its cover in an open state. Referring to FIGS. 1 and 2, the wafer transfer cassette includes a wafer storage frame 10, a base 20, a casing 30, a cover 40 and a rotary coupling mechanism 60 (not shown in FIGS. 1 and 2). The wafer storage frame 10 is configured to accommodate wafers. The base 20 and the casing 30 are fixedly connected to each other and together define a cavity 71 in which the wafer storage frame 10 is accommodated. The cavity 71 is in general cylindrical. The casing 30 defines an opening 72, through which wafers can be placed in or taken out. The cover 40 is arched and pivotally coupled to the casing 30 by the rotary coupling mechanism 60 so that when the rotary coupling mechanism 60 rotates, the cover 40 slides along the base 20 to open or close the opening 72.

In the wafer transfer cassette provided in the present embodiment, since the wafer storage frame 10 configured to store wafers is accommodated in the cavity 71 defined by the base 20 and casing 30, wafer contamination during transportation can be prevented. Additionally, the cover 40 of the cassette is driven to move along an arched path by the rotary coupling mechanism, which cause the cover 40 to open or close the opening 72 which is defined in the casing 30 and configured to allow wafers to be placed in or taken out, and thus automatic opening and closing of the wafer transfer cassette can be achieved.

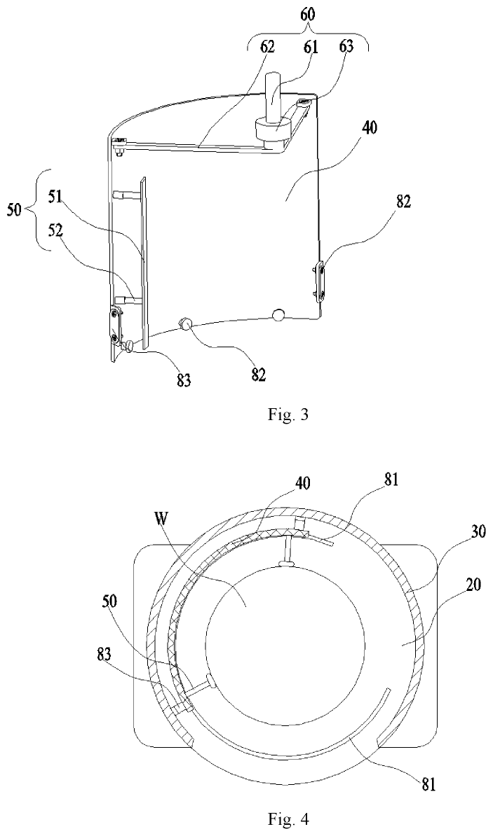

FIG. 3 is a schematic structural diagram of a part of the wafer transfer cassette according to an embodiment of the present invention, while FIG. 4 is a simplified schematic cross-sectional view of the wafer transfer cassette according to an embodiment of the present invention. In this embodiment, with reference to FIGS. 3 and 4, the wafer transfer cassette may further include a pressing mechanism 50, which is connected to the cover 40 in a scalable manner and able to adjust positions of wafers in the wafer storage frame 10 during movement of the cover 40. During or after placement of wafers into the wafer storage frame 10 through the opening 72, the wafers may be not all situated at their respective desired positions (i.e., the wafers are not aligned with one another). At this point, when the cover 40 is caused to move to open or close the opening 72, the cover 40 is likely to be stuck by the wafers W loaded in the wafer storage frame 10. This may hinder the automatic opening/closing of the wafer transfer cassette or cause damage to the wafers W. In the wafer transfer cassette according to this embodiment, when the cover 40 moves along the arched path to close or open the opening 72 in the casing 30, the pressing mechanism 50 fixedly disposed on the cover 40 is able to adjust the positions of the wafers in the wafer storage frame 10. That is, it is possible to adjust the positions of the wafers in the wafer storage frame 10 while the cover 40 is moving to open or close the opening 72, thereby preventing the cover 40 from being unintentionally stuck, and avoiding malfunctioning of the wafer transfer cassette and damage to the wafers W. Further, after the cover 40 is closed, the pressing mechanism 50 is able to limit the wafers to desired positions in the wafer storage frame 10 so that displacement of the wafers in the wafer storage frame 10 can be avoided.

Specifically, referring to FIG. 3, in this embodiment, the pressing mechanism 50 may include a push bar 51, scalable links 52 and springs (not shown). Each of the scalable links 52 has two ends respectively connected to the cover 40 and push bar 51. The scalable links 52 are configured to support the push bar 51. The springs sleeve over the respective scalable links 52 and configured to provide the push bar 51 with preloads during the movement of the push bar 51 along an axial direction of the scalable links 52. The push bar 51 is configured to adjust positions of wafers W loaded in the wafer storage frame 10 during movement of the cover 40. In other words, while the cover 40 is moving, the push bar 51 may push the wafers W, thereby adjusting their positions. It is to be noted that, in this embodiment, with the cover 40 moving in the arched path, the push bar 51 will slide along outer circumferential edges of the wafers W to push some of the wafers, that are not loaded at their desired positions precisely, at their outer circumferential edges so that the positions of the wafers can be adjusted.

In this embodiment, the wafer transfer cassette may include at least one pressing mechanism 50, and each push bar 51 may be able to adjust at least one wafer W at a single time.

The push bar 51 may be elastic so that it may come into contact with and be pressed by the wafers W during the movement of the cover 40. In such way, the positions of the wafers W can be adjusted effectively without causing any damage to the wafers W.

When the cover 40 is moving, the scalable links 52 may move either toward or away from the cover 40, with the springs always pressing the push bar 51 against wafers in the wafer storage frame 10. With this design, the contact between the push bar 51 and wafers can be buffered by the springs, thus avoiding impact damage to the wafers during adjustment of the wafers by the push bar 51 in the pressing mechanism 50.

Preferably, a longitudinal direction of the push bar 51 is parallel to an axis of the wafer storage frame 10 along which the wafers are arranged. Additionally, a length of the push bar 51 is preferred to be not less than a total height of the wafer able to be stored in the wafer storage frame 10.

Preferably, the base is provided thereon with a guide member 81 configured to guide the cover for sliding. The presence of the guide member 81 makes it possible to prevent the cover 40 from being stuck in movement.

Preferably, at least one rolling bearing 82 (see FIG. 3) is provided on an inner side of the cover 40 in order to facilitate the sliding movement of the cover. With the aid of the rolling bearing 82, the cover 40 can slide smoothly with reduced generation of wafer-contaminating particles from friction, thereby reducing the risk of contamination to the wafers from the particles. The rolling bearing 82 is preferably a resin bearing.

Preferably, the guide member 81 may be implemented as an arched groove along which the cover can slide.

Referring to FIG. 3, in this embodiment, the rotary coupling mechanism 60 of the wafer transfer cassette may include a rotating shaft 61 and connecting members 62. The rotating shaft 61 is disposed on the casing 30, while each of the connecting members 62 is fixedly connected to the cover 40 at one end and coupled to the rotating shaft 61 at the other end. The rotating shaft 61 is configured to drive the connecting members 62 to pivot so as to cause the cover 40 fixedly connected to the connecting members 62 to rotate about an axis of the rotating shaft 61, i.e., to cause the cover 40 to move along the arched path.

Specifically, the connecting members 62 may be implemented as link bars, and the number of the link bars may be at least two. In case of two link bars, they may be fixedly connected between the cover and the rotating shaft and arranged at a certain angle with respect to each other.

Specifically, referring to FIG. 3, the cover 40 may further include a bearing seat 63 and a bearing (not shown) fixed to the casing 30 by the bearing seat 63. One end of the rotating shaft 61 passing through the bearing may be fixedly connected to the connecting members 62, and the other end of the rotating shaft 61 protruding out of the casing 30 serves as a driving end.

Preferably, the casing 30 may include a top 31 opposite the base 20, and the rotating shaft 61 may be disposed on the top 31. Specifically, the rotating shaft 61 may be inserted through, and rotatably coupled to, the top 31 of the casing 30. Preferably, the rotating shaft 61 is disposed at a center of the top 31 of the casing 30. This design allows a reduction in the size, and hence in the weight, of the wafer transfer cassette, compared to a design with the rotating shaft 61 not arranged at the center of the top 31. Further, in this embodiment, the position of the top 31 of the casing 30 is described only in relation to the base 20 and does not limit the actual shape or orientation of the wafer transfer cassette in any sense.

Referring to FIGS. 1 and 2, in this embodiment, the casing 30 may be provided, on the side facing away from the cavity 71, a first connecting portion 32 configured to connect an automated transfer apparatus. The automated transfer apparatus is configured to grasp the first connecting portion 32 and to transport the wafer transfer cassette.

Specifically, the first connecting portion 32 may be disposed on the side of the top 31 of the casing 30 that faces away from the cavity 71. The first connecting portion 32 may be a recess or a protrusion. The automated transfer apparatus may be an overhead hoist transport (OHT) or an automated guided vehicle (AGV). In this way, the wafer transfer cassette may be compatibly integrated into a transportation system of an existing production line without requiring additional adaptations. Of course, the automated transfer apparatus may also be any other suitable transfer apparatus commonly used in IC production lines.

Preferably, the first connecting portion 32 may be a flange. Preferably, the first connecting portion 32 may be arranged at the center of the top 31 of the casing 30. In this case, during transportation of the wafer transfer cassette by the transfer apparatus, any tilt of the wafer transfer cassette causing movements of the wafers in the wafer transfer cassette can be avoided, and thus any damage to the wafers from the movements can be also avoided.

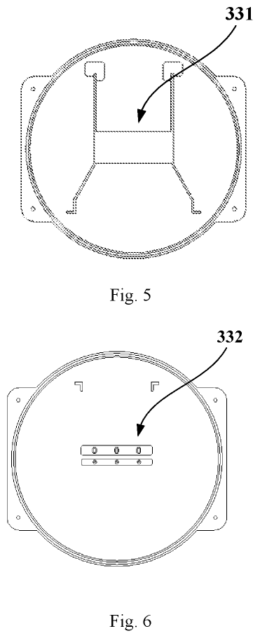

As shown in FIG. 5, the base 20 may be provided thereon with a frame locating mechanism configured to engage with a bottom of the wafer storage frame 10. In this embodiment, the frame locating mechanism may be a frame locating groove 331 formed in the base 20, and the bottom of the wafer storage frame 10 may engage with the frame locating groove 331 by snap fit.

Referring to FIGS. 3 and 4, in this embodiment, at least one attractive fastener assembly 83 may be provided on both a side of the cover 40 along the sliding direction and a side of the casing 30 corresponding to the side of the cover. Preferably, two attractive fastener assemblies 83 are provided on both a side of the cover 40 along the sliding direction and a side of the casing 30 corresponding to the side of the cover. When the opening is fully closed or opened, the attractive fastener assemblies 83 can function to fasten the cover 40 to the casing 30.

Specifically, each of the attractive fastener assemblies 83 may consist of a magnetic button and a magnetic bar which are magnetically attracted with each other. The magnetic button may be arranged on the cover 40 and the magnetic bar may be arranged on the casing 30, and vice versa.

In this embodiment, referring to FIG. 1, the wafer storage frame 10 is configured to store wafers and is an open structure in which the wafers are directly exposed. For example, the wafer storage frame 10 may include a plurality of wafer support each configured to receive a single wafer. Adjacent ones of the wafer slots may be separated by a certain distance in order to create an interval between the wafers. Preferably, the wafer storage frame 10 may be either a wafer cassette or a standard mechanical interface (SMIF) pod used in the existing production lines. The wafer storage frame 10 may be either of a vertical type with its axis perpendicular to a horizontal plane or of a horizontal type with its axis parallel to a horizontal plane. In both cases, in the wafer transfer cassette according to this embodiment, the axis of the rotating shaft 61 is parallel to the axis of the wafer storage frame 10.

In this embodiment, it also provides an automated wafer transfer system including the wafer transfer cassette as defined above, a rotary driving mechanism configured to cause rotation of the rotary coupling mechanism and an automated transfer apparatus for transporting the wafer transfer cassette by grasping the first anchoring member 32. The automated wafer transfer system is configured to enable automated material transfer in an IC production line. The wafer transfer cassette may be transported between multiple wafer processing stations, or between wafer processing stations and wafer transfer cassette buffer areas, or between multiple such buffer areas.

Optionally, the automated wafer transfer system may further include a wafer cassette stage provided in each of the wafer processing stations and/or wafer transfer cassette buffer areas. The wafer cassette stage may have a bearing surface onto which the wafer transfer cassette is connected with a positional limitation, so that the wafer transfer cassette can be fixed to the wafer cassette stage.

In this embodiment, the frame locating groove 331 in the base 20 may have a depth that is not less than a thickness of the base 20 so that the bottom of the wafer storage frame 10 can be went through the frame locating groove 331 and thus come into contract with the wafer cassette stage. The same groove as the frame locating groove 331 may be formed in the bearing surface of the wafer cassette stage so that the wafer storage frame 10 can engage with both the base 20 and the bearing surface of the wafer cassette stage.

### Embodiment 2

As shown in FIG. 6, this embodiment differs from Embodiment 1 in that the frame locating mechanism is implemented as a frame locating protrusion 332 which can engage with the bottom of the wafer storage frame 10 to limit the position of the wafer storage frame 10.

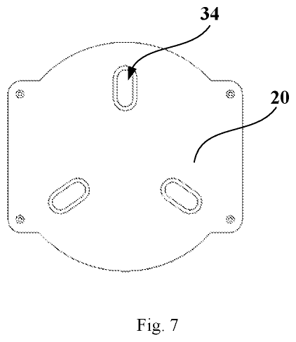

Optionally, an automated wafer transfer system incorporating the wafer transfer cassette of Embodiment 2 may also include a wafer cassette stage having a bearing surface that can be connected to a bottom side of the base 20 with a positional limitation. In particularly, locating legs 34 may be formed on the lower surface of the base 20. Accordingly, corresponding locating receptacles are formed in the bearing surface of the wafer cassette stage, as shown in FIG. 7, and vice versa.

The wafer transfer cassette of the present invention can be used to transport wafers of different sizes including, but not limited to, 8″ and 12″. Specifically, the base 20 described in Embodiment 1 is suitable for wafer storage frames 20 for 8″ wafers, while that of Embodiment 2 is suitable for wafer storage frames 20 for 12″ wafers.

The description presented above is merely that of a few preferred embodiments of the present invention and does not limit the scope thereof in any sense. Any and all changes and modifications made by those of ordinary skill in the art based on the above teachings fall within the scope as defined in the appended claims.

1. A wafer transfer cassette, configured to accommodate a wafer storage frame, wherein the wafer transfer cassette comprises a base, a casing, a cover and a rotary coupling mechanism, the base and the casing being fixedly connected to each other and together define a cavity for accommodating the wafer storage frame, the casing defining an opening through which a wafer can be placed in or taken out, the cover pivotably coupled to the casing by means of the rotary coupling mechanism so that when the rotary coupling mechanism rotates, the cover slides on the base and thus opens or closes the opening.

2. The wafer transfer cassette of claim 1, further comprising a pressing mechanism, which is disposed on a surface of the cover that faces toward the wafer storage frame and is elastically scalable with respect to the cover, wherein during movement of the cover, the pressing mechanism is able to apply a force to a wafer in the wafer storage frame in a plane of the wafer so as to adjust the position of the wafer.

3. The wafer transfer cassette of claim 2, wherein the pressing mechanism comprises a push bar, a scalable link and a spring, the scalable link having two ends respectively connected to the cover and the push bar, the spring sleeving over the scalable link, the spring configured to provide the push bar with an axial preload during movement of the push bar in an axial direction of the scalable link.

4. The wafer transfer cassette of claim 3, wherein a lengthwise direction of the push bar is parallel to an axis of the wafer storage frame, and wherein a length of the push bar is not less than a total height of wafers able to be stored in the wafer storage frame.

5. The wafer transfer cassette of claim 1, wherein the base is provided thereon with a guide member configured to guide the cover to slide.

6. The wafer transfer cassette of claim 5, wherein the guide member is a groove formed in the base, and the cover is able to slide along the groove.

7. The wafer transfer cassette of claim 1, further comprising at least one rolling bearing fixed to an inner side of the cover and brought into rollable contact with the base.

8. The wafer transfer cassette of claim 7, wherein the rolling bearing is a resin bearing.

9. The wafer transfer cassette of claim 1, wherein the rotary coupling mechanism comprises a rotating shaft, a rotating bearing and a connecting member, the rotating bearing being fixed to the casing, one end of the rotating shaft going through the rotating bearing and coupled to one end of the connecting member, a further end of the rotating shaft protruding out of the casing and serving as a driving end, a further end of the connecting member fixedly connected to the cover.

10. The wafer transfer cassette of claim 9, wherein the casing comprises a top opposite the base, the rotating shaft protruding out of, and rotatably coupled to, the top of the casing, and wherein the rotating shaft is disposed at a center of the top of the casing.

11. The wafer transfer cassette of claim 9, wherein the connecting member is implemented as a link bar, wherein at least two link bars are disposed between the cover and the rotating shaft and arranged at an angle with respect to each other.

12. The wafer transfer cassette of claim 1, wherein the base is provided thereon with a frame locating mechanism configured to match and connect with a bottom of the wafer storage frame.

13. The wafer transfer cassette of claim 12, wherein the frame locating mechanism is a frame locating groove or a frame locating protrusion.

14. The wafer transfer cassette of claim 1, wherein attractive fastener assemblies are respectively provided on two sides of the cover along a slide direction of the cover and at corresponding locations of the casing, in order to attach the cover to the casing by attraction when the opening is fully closed or fully opened.

15. The wafer transfer cassette of claim 1, wherein the cover is arched and configured to slide along an arched path on the base in order to open or close the opening.

16. An automated wafer transfer system, configured to transfer wafers between a plurality of wafer processing stations, between the plurality of wafer processing stations and a plurality of wafer storage areas, and/or between the plurality of wafer storage areas, wherein the automated wafer transfer system comprises a wafer transfer cassette, a rotary driving mechanism and an automated transfer apparatus;
wherein the wafer transfer cassette is configured to accommodate a wafer storage frame, wherein the wafer transfer cassette comprises a base, a casing, a cover and a rotary coupling mechanism, the base and the casing being fixedly connected to each other and together define a cavity for accommodating the wafer storage frame, the casing defining an opening through which a wafer can be placed in or taken out, the cover pivotably coupled to the casing by means of the rotary coupling mechanism so that when the rotary coupling mechanism rotates, the cover slides on the base and thus opens or closes the opening, a flange is arranged on the casing of the wafer transfer cassette;
the rotary driving mechanism is configured to cause a rotation of the rotary coupling mechanism; and
the automated transfer apparatus is configured to transport the wafer transfer cassette by grasping the flange.

17. The automated wafer transfer system of claim 16, wherein each of the wafer processing stations and/or wafer storage areas is provided with a wafer cassette stage having a bearing surface configured to match and connect with the wafer transfer cassette.
